(19) United States
(12) Patent Application Publication
(10) Pub. No.: US 2012/0267747 A1
(43) Pub. Date: Oct. 25, 2012

(54) SOLID-STATE IMAGE PICKUP DEVICE AND METHOD FOR MANUFACTURING THE SAME

(75) Inventors: Takanori Watanabe, Yamato-shi (JP); Masatsugu Itahashi, Yokohama-shi (JP); Masahiro Kobayashi, Tokyo (JP); Hideo Kobayashi, Tokyo (JP); Tetsuya Fudaba, Ebina-shi (JP); Takeshi Ichikawa, Hachioji-shi (JP)

(73) Assignee: CANON KABUSHIKI KAISHA, Tokyo (JP)

(21) Appl. No.: 13/512,313

(22) PCT Filed: Nov. 29, 2010
(86) PCT No.: PCT/JP2010/006947

§ 371 Date: May 25, 2012

(30) Foreign Application Priority Data
Dec. 4, 2009 (JP) 2009-276834

(51) Int. Cl. H01L 31/02

(52) U.S. Cl. 257/443; 438/73; 257/E31.113

(57) ABSTRACT

A solid-state image pickup device according to the present invention is a backside-illuminated solid-state image pickup device that includes a plurality of pixels each having a photoelectric conversion portion. A p-type semiconductor region 110 in which holes are collected is disposed on the front side of a PD substrate 101. An n-type semiconductor region 119 is disposed below the p-type semiconductor region 110 on the back side of the PD substrate 101. The n-type semiconductor region 119 contains arsenic as a principal impurity. The photoelectric conversion portion includes the p-type semiconductor region 110 and the n-type semiconductor region 119.

### TECHNICAL FIELD

The present invention relates to a solid-state image pickup device and, more particularly, to a backside-illuminated solid-state image pickup device, a method for manufacturing the solid-state image pickup device, and a camera system.

### BACKGROUND ART

In recent years, backside-illuminated solid-state image pickup devices have been proposed as high-sensitivity solid-state image pickup devices. In the backside-illuminated solid-state image pickup devices, transistors and metal wires are disposed on a first main surface side (the front side) of a semiconductor substrate, and light enters through a second main surface side (the back side) opposite to the front side.

PTL 1 discloses a solid-state image pickup device of a charge modulation device (CMD) type, which modulates the channel current of a detection transistor by accumulating holes of electron-hole pairs as signal carriers. The electron-hole pairs are generated by the photoelectric conversion of light incident from the back side. More specifically, FIG. 2 in PTL 1 illustrates a structure including a photo detector for the photoelectric conversion of light incident from the back side in a solid-state image pickup device of a CMD type. The photo detector illustrated in FIG. 2 in PTL 1 has a low-concentration p-type semiconductor region for photoelectric conversion, a p-type semiconductor region in which holes are accumulated, and a high-concentration n-type semiconductor region on a main surface on the back side, which is a light incident surface.

PTL 1 does not specifically disclose species of ions contained in the high-concentration n-type semiconductor region. Some species of ions may broaden the high-concentration n-type semiconductor region disposed on the main surface on the light incident surface side because of impurity diffusion. This would flatten the potential distribution in the vicinity of the main surface on the light incident surface side, making it difficult for holes generated in the vicinity of the main surface on the light incident surface side to be collected in the accumulation region. This would make it difficult to achieve high sensitivity. Holes not collected in the accumulation region may enter adjacent pixels and generate noise or may cause color mixing in color image pickup devices.

### CITATION LIST

### Patent Literature

PTL 1: Japanese Patent Laid-Open No. 2008-294176

### SUMMARY OF INVENTION

In view of the problems described above, the present invention provides a high-sensitivity backside-illuminated solid-state image pickup element with little color mixing.

A backside-illuminated solid-state image pickup device according to one aspect of the present invention includes a semiconductor substrate in which a plurality of pixels each having a photoelectric conversion portion are disposed and a wiring layer disposed on a first main surface side of the semiconductor substrate. Light enters the photoelectric conversion portion from a second main surface opposite to the first main surface of the semiconductor substrate. The photoelectric conversion portion includes a first n-type semiconductor region and a first p-type semiconductor region. The first n-type semiconductor region contains arsenic as a principal impurity. The first n-type semiconductor region is disposed closer to the second main surface of the semiconductor substrate than the first p-type semiconductor region is. A hole generated by photoelectric conversion is collected in the first p-type semiconductor region as a signal carrier.

A method for manufacturing a solid-state image pickup device according to one aspect of the present invention includes implanting arsenic ions into a second main surface of a semiconductor substrate, reducing the thickness of the semiconductor substrate from a first main surface side opposite to the second main surface, attaching a processing substrate to the second main surface side of the semiconductor substrate, forming a wiring layer on the first main surface side of the semiconductor substrate, and removing the processing substrate.

A method for manufacturing a solid-state image pickup device according to another aspect of the present invention includes forming a wiring layer on a first main surface of a semiconductor substrate, reducing the thickness of the semiconductor substrate from a second main surface side opposite to the first main surface, and implanting arsenic ions into the second main surface of the semiconductor substrate.

A method for manufacturing a solid-state image pickup device according to another aspect of the present invention includes implanting arsenic ions into a silicon-on-insulator (SOI) layer of an SOI substrate, the SOI substrate including the SOI layer, a buried oxide (BOX) layer, and a bulk substrate, forming a silicon film on the SOI layer by epitaxial growth, forming a wiring layer on a side of the SOI layer opposite to the BOX layer, and removing the bulk substrate.

### ADVANTAGEOUS EFFECTS OF INVENTION

A solid-state image pickup device according to one aspect of the present invention can be a high-sensitivity backside-illuminated solid-state image pickup device.

Further features of the present invention will become apparent from the following description of exemplary embodiments with reference to the attached drawings.

### BRIEF DESCRIPTION OF DRAWINGS

FIG. 1A is a schematic cross-sectional view of a solid-state image pickup device according to a first embodiment of the present invention.

FIG. 1B is an impurity profile in the depth direction for a photoelectric conversion portion according to the first embodiment.

FIGS. 2A to 2E illustrate a process for manufacturing the solid-state image pickup device according to the first embodiment of the present invention.

FIG. 3 is a schematic cross-sectional view of a solid-state image pickup device according to a second embodiment of the present invention.

FIG. 4A is a schematic cross-sectional view of a solid-state image pickup device according to a third embodiment of the present invention.

FIG. 4B is an impurity profile in the depth direction for a photoelectric conversion portion according to the third embodiment.

FIG. 5A is a schematic cross-sectional view of a solid-state image pickup device according to a fourth embodiment of the present invention.

FIG. 5B is an impurity profile in the depth direction for a photoelectric conversion portion according to the fourth embodiment.

FIGS. 6A to 6C illustrate a process for manufacturing the solid-state image pickup device according to the fourth embodiment of the present invention.

FIG. 7A is a schematic cross-sectional view of a solid-state image pickup device according to a fifth embodiment of the present invention.

FIG. 7B is an impurity profile in the depth direction for a photoelectric conversion portion according to the fifth embodiment.

FIG. 8A is a schematic cross-sectional view of a solid-state image pickup device according to a sixth embodiment of the present invention.

FIG. 8B is an impurity profile in the depth direction for a photoelectric conversion portion according to the sixth embodiment.

FIGS. 9A to 9C illustrate a process for manufacturing the solid-state image pickup device according to the sixth embodiment of the present invention.

FIGS. 10A to 10C illustrate a process for manufacturing the solid-state image pickup device according to a seventh embodiment of the present invention.

FIGS. 11A to 11C illustrate a process for manufacturing the solid-state image pickup device according to an eighth embodiment of the present invention.

FIG. 12 is a block diagram of a camera system according to an embodiment of the present invention.

### DESCRIPTION OF EMBODIMENTS

Embodiments of the present invention will be described in detail below with reference to the drawings. In the present invention, holes are used as signal carriers.

The term “semiconductor substrate”, as used herein, refers to a semiconductor region in a wafer or a chip. The term “a main surface of a semiconductor substrate”, as used herein, refers to an interface between a semiconductor region in a wafer or a chip and another substance. For example, surfaces of general silicon wafers in contact with air are covered with an oxide film. In this case, a main surface of a semiconductor substrate refers to an interface between a silicon region and the oxide film. When the position of an interface varies, for example, by thermal oxidation, the new interface becomes a main surface.

### First Embodiment

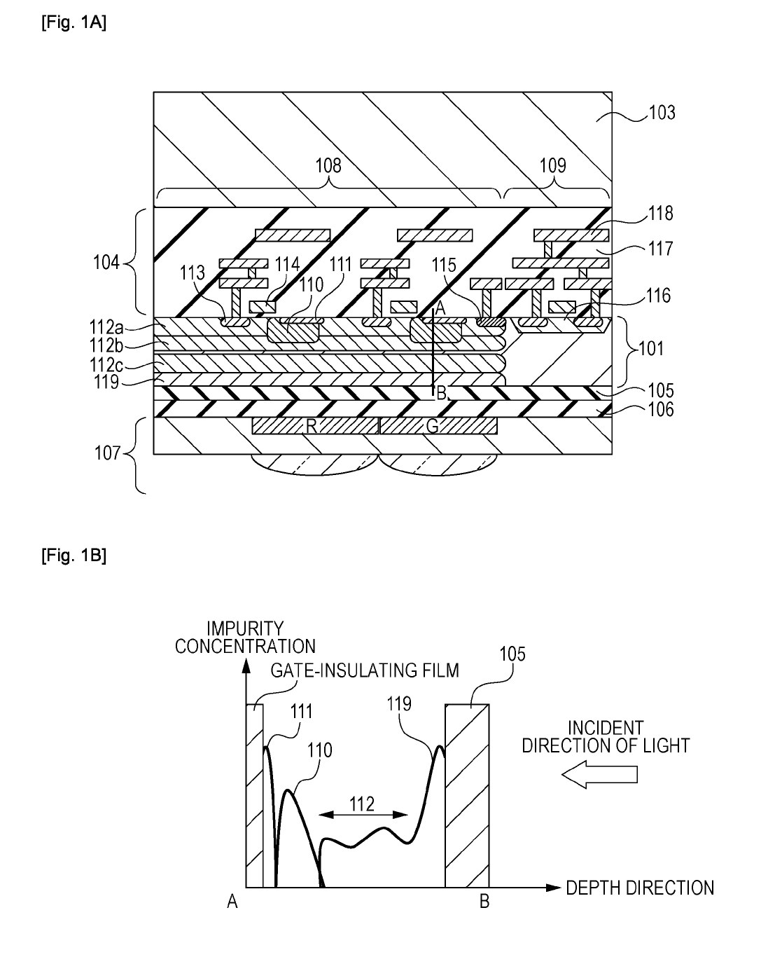

FIG. 1A is a schematic cross-sectional view of a solid-state image pickup device according to a first embodiment of the present invention. A photoelectric conversion portion and semiconductor regions of transistors are formed in a semiconductor substrate 101 (hereinafter referred to as a PD substrate for convenience). The PD substrate 101 may be a p-type semiconductor substrate, an n-type semiconductor substrate, an SOI substrate, or the like. Details will be described below. A wiring portion 104 is disposed on a first main surface side (the front side) of the PD substrate. A supporting substrate 103 may be disposed on the wiring portion 104, that is, on a side of the wiring portion 104 opposite to the PD substrate 101 primarily for the purpose of maintaining the strength of the substrate. An insulating film 105 is disposed on a second main surface of the PD substrate 101. If necessary, a protective film 106 and an optical function portion 107 are disposed on the second main surface side (the back side) of the PD substrate 101, that is, on a side opposite to the wiring portion 104 through the insulating film 105. Thus, the present embodiment has a structure of a backside-illuminated solid-state image pickup device, in which light enters through a side opposite to the first main surface on which wiring and transistors are disposed, that is, light enters through the back side.

The schematic cross-sectional view of FIG. 1A schematically illustrates a pixel region 108 and a peripheral circuit region 109. A plurality of pixels are disposed in the pixel region 108. Each of the pixels includes a photoelectric conversion portion for the photoelectric conversion of incident light. Although the pixel region 108 includes only two pixels in FIG. 1A, three or more pixels may be arranged in a matrix or line. A circuit for reading signals from the pixels is formed in the peripheral circuit region 109. The peripheral circuitry includes, for example, a scanning circuit composed of a shift register and a decoder. The peripheral circuitry may also include a readout circuit portion for the signal processing, such as amplification, of signals output from the photoelectric conversion portion.

The structure of the photoelectric conversion portion in the pixel region 108 will be described below. A p-type semiconductor region 110, which can collect holes, is disposed in the vicinity of the front side of the PD substrate 101. A high-concentration n-type semiconductor region 111 is disposed on the front side of the p-type semiconductor region 110. An insulating film is also disposed on the front side of the PD substrate 101. The high-concentration n-type semiconductor region 111 can prevent electric charges generated at the interface between the insulating film on the front side and the high-concentration n-type semiconductor region 111 from entering the p-type semiconductor region 110. The p-type semiconductor region 110 corresponds to the first p-type semiconductor region in the Claims.

A pixel well 112 is disposed all along the pixel region 108. The pixel well 112 is an n-type semiconductor region that contains phosphorus as a principal impurity. The p-type semiconductor region 110 and the pixel well 112 form a p-n junction. An n-type semiconductor region 119 is disposed on the back side of the PD substrate 101. In the present embodiment, the n-type semiconductor region 119 corresponds to the first n-type semiconductor region, and the pixel well 112 corresponds to the second n-type semiconductor region in the Claims.

The photoelectric conversion portion includes the p-type semiconductor region 110, the high-concentration n-type semiconductor region 111, the pixel well 112, and the n-type semiconductor region 119. The photoelectric conversion portion in the present embodiment is a buried photodiode.

A floating diffusion (hereinafter referred to as an FD) 113 composed of a p-type semiconductor region is disposed on the front side of the PD substrate 101. The FD 113 is provided with a contact plug, which is electrically connected to an input of an amplifier (not shown). A transfer gate electrode 114 is disposed on the PD substrate between the p-type semiconductor region 110 and the FD 113 through the insulating film.

A bias supplied to the transfer gate electrode 114 forms a transfer path from the p-type semiconductor region 110 to the FD 113. The formation of the transfer path allows the complete depletion transfer of holes from the p-type semiconductor region 110 to the FD 113. The amplifier outputs signals corresponding to the number of holes transferred to the FD 113. The transfer gate electrode 114 and the transfer path constitute a transfer portion for transferring holes collected in the p-type semiconductor region 110 to the FD.

An n-type semiconductor region 115 is a well contact region and is electrically connected to an electrode for setting the electric potential of the pixel well 112 and the n-type semiconductor region 119. The well contact region 115 may be arranged at regular intervals in the pixel region 108 or may be disposed at the boundary between the pixel region 108 and the peripheral circuit region 109.

A peripheral circuit well 116 is disposed in the peripheral circuit region 109 of the PD substrate 101. For example, a MOS transistor is disposed in the peripheral circuit well 116. More specifically, an NMOS transistor is formed in a periphera circuit well 116 composed of a p-type semiconductor region, and a PMOS transistor is formed in a peripheral circuit well 116 composed of an N-type semiconductor region. Although only a single peripheral circuit well is illustrated in FIG. 1, peripheral circuit wells of different conductive types may be disposed. In both conductive types, the peripheral circuit well 116 can have a higher impurity concentration than the PD substrate. This allows a transistor in the peripheral circuitry to be finely formed.

The wiring portion 104 has a multilayer wiring structure in which a plurality of wiring layers 118 are stacked with an interlayer insulating film 117 interposed therebetween. The wiring portion 104 may have a monolayer wiring structure, which includes only a single wiring layer. The supporting substrate 103 on the wiring portion 104 may be formed of silicon. The protective film 106 may be formed of silicon nitride. The optical function portion 107 includes a microlens, a color filter, and a waveguide.

The n-type semiconductor region 119 contains arsenic as the dominant impurity. When arsenic is added into silicon crystals as an impurity, a strain caused by a difference in lattice constant from silicon is small. The n-type semiconductor region 119 disposed in contact with the insulating film 105 on the back side of the PD substrate 101 can lower the number of interface states and prevent the frequent generation of dark current, for example, as compared with the addition of phosphorus as a principal impurity.

FIG. 1B shows an impurity concentration profile along the line AB in FIG. 1A. In FIG. 1B, the vertical axis represents the impurity concentration, and the horizontal axis represents the depth from the surface. In the present specification, the depth direction is a direction perpendicular to the front side or back side of the substrate. AB in FIG. 1A therefore indicates the depth direction.

As illustrated in FIG. 1B, the impurity concentration peak of the high-concentration n-type semiconductor region 111 is closest to the front side of the PD substrate 101. The impurity concentration peak of the p-type semiconductor region 110 is located deeper than the impurity concentration peak of the high-concentration n-type semiconductor region 111. The semiconductor region of the pixel well 112 is disposed below the p-type semiconductor region 110. The impurity concentration peak of the n-type semiconductor region 119 is closest to the back side of the PD substrate 101.

The n-type semiconductor region 119 contains arsenic as a principal impurity. Since arsenic has a larger mass than phosphorus or boron, arsenic has a smaller diffusion co-efficient and is less diffusive during thermal treatment. Thermal treatment therefore does not significantly alter the impurity distribution formed by ion implantation. Thus, the n-type semiconductor region 119 can have a sharp impurity concentration peak.

Such a structure can provide a steep potential gradient from the back side to the front side. Holes generated by photoelectric conversion in the vicinity of the interface, therefore, move fast toward the p-type semiconductor region 110. Thus, holes in the vicinity of a light incident surface, on which photocharges are most frequently generated, can be efficiently collected in the p-type semiconductor region 110.

The present embodiment allows for the complete depletion transfer of holes from the p-type semiconductor region 110 to the FD 113. In order to achieve the complete depletion transfer with high precision, the photoelectric conversion portion is desired to have a wide range of variation of feasible designs. Since arsenic is less diffusive as described above, the thickness of the photoelectric conversion portion can be designed with a high precision.

The pixel well 112 contains phosphorus as a principal impurity. Since phosphorus has a large diffusion coefficient, the pixel well 112 has a gentle impurity concentration peak. Thus, the pixel well 112 has a gradual potential and does not significantly prevent holes from moving into the p-type semiconductor region 110. Furthermore, since phosphorus has a large penetration depth, the pixel well 112 can be deepened.

The pixel well 112 can be formed by phosphorus ion implantation. The energy and dose of ion implantation can be controlled. It is possible to stably form a desired impurity distribution by controlling the energy and dose of ion implantation. Ion implantation can therefore improve process stability and yield.

The pixel well 112 is not essential for the present invention. The p-type semiconductor region 110 and the n-type semiconductor region 119 may form a p-n junction.

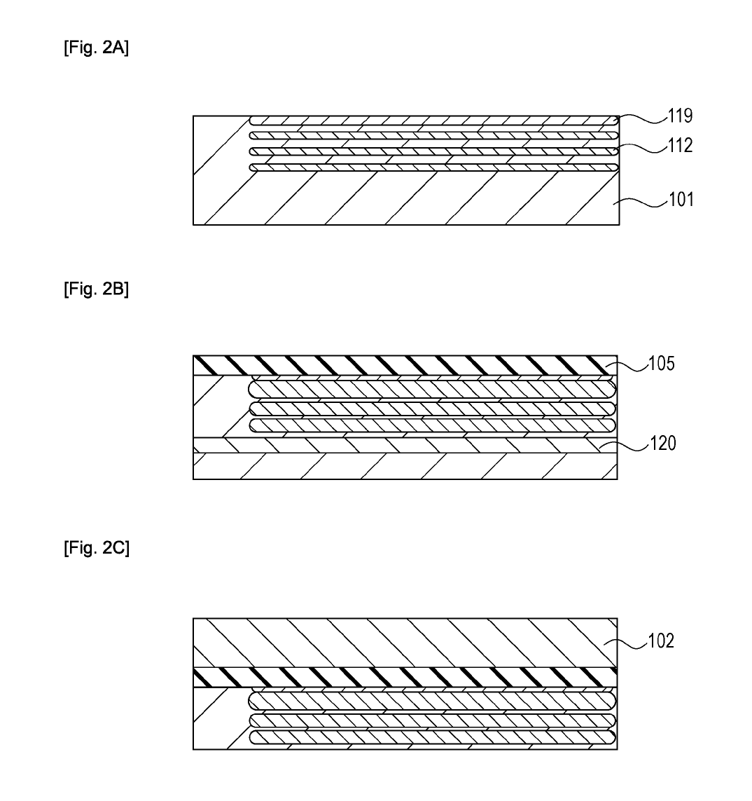

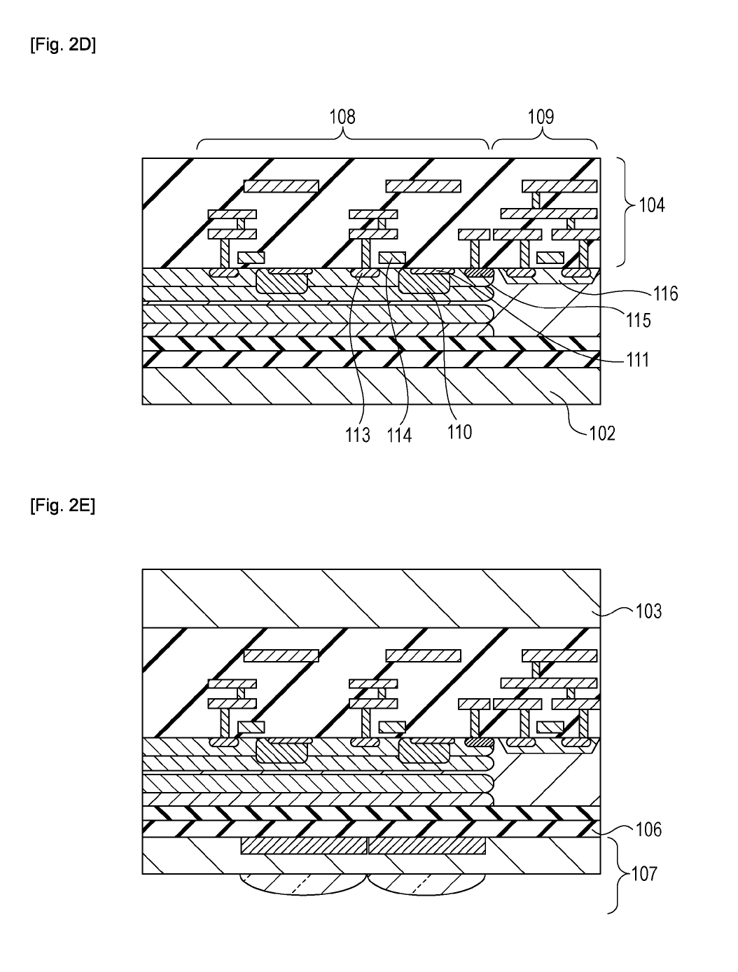

A process for manufacturing a solid-state image pickup device according to the present embodiment will be described below with reference to the drawings. In the present embodiment, the PD substrate 101 is a p-type silicon substrate. In FIG. 2A, the upper side corresponds to the back side (the incident surface), and the lower side corresponds to the front side (a side on which a wiring portion is formed). As illustrated in FIG. 2A, in order to form the n-type semiconductor region 119 and the pixel well 112 in the PD substrate 101, arsenic ion implantation and phosphorus ion implantation can be performed respectively from the upper side in the drawing. Phosphorus ion implantation for the formation of the pixel well 112 is performed more than once at different implantation energies in this embodiment. The pixel well 112 can be formed by phosphorus ion implantation performed only once. In the present embodiment, ion implantation is performed in the pixel region 108 using a resist mask and is not performed in the peripheral circuit region 109.

Next, the PD substrate 101 is thermally processed in an oxygen atmosphere to form an oxide film as the insulating film 105 and activate the impurities. Annealing for impurity activation and the deposition of the oxide film may be performed in different steps.

As illustrated in FIG. 2B, a separation layer 120 is formed closer to the front side than the pixel well 112 is. When part of the PD substrate 101 is removed to reduce the thickness in the subsequent step, the part of the PD substrate 101 is removed with the separation layer 120 as a boundary. The separation layer 120 can be formed by hydrogen ion implantation.

The separation layer 120 may be formed as an etch-stop layer. In the removal of part of the PD substrate 101 by etching, a layer having a low etch rate can function as an etch-stop layer. For example, an oxide film may be formed by oxygen ion implantation, or the impurity concentration of an etch-stop layer may be made different from the impurity concentration of the PD substrate 101 by boron or phosphorus implantation.

Subsequently, as illustrated in FIG. 2C, a processing substrate 102 is attached to the insulating film 105. The processing substrate 102 is supported by a processing apparatus in the subsequent steps: formation of elements and wiring on the front side of the PD substrate 101. If the PD substrate 101 is a silicon substrate, it is desirable that the processing substrate 102 also be a silicon substrate. This can reduce the difference in thermal expansion coefficient between the PD substrate 101 and the processing substrate 102, thereby preventing warping and detachment of the processing substrate 102.

Part of the PD substrate 101 is then removed with the separation layer 120 as a boundary. If there is an etch-stop layer, part of the PD substrate 101 is removed by etching to reduce the thickness of the PD substrate 101. A portion of the PD substrate 101 in which semiconductor regions are formed is not removed.

As illustrated in FIG. 2D, after the substrate is turned upside down, semiconductor regions and gate electrodes constituting the pixel region 108 and the peripheral circuit region 109 and then the wiring portion 104 are formed on the front side (the upper side in FIG. 2D), for example, by a known method.

Subsequently, as illustrated in FIG. 2E, the supporting substrate 103 is attached to a side of the wiring portion 104 opposite to the PD substrate 101. The supporting substrate 103 increases the mechanical strength of the PD substrate 101. A silicon substrate may be used for the supporting substrate 103.

The processing substrate 102 is then removed by polishing and etching using the insulating film 105 as an etch-stop layer.

After the processing substrate 102 is removed, if necessary, the protective film 106 and the optical function portion 107 are formed on the back side. In the present embodiment, the protective film 106 is a nitride film and is provided with a color filter and a microlens thereon.

In the present embodiment, since the n-type semiconductor region 119 contains arsenic as the dominant impurity, as described above, the n-type semiconductor region 119 has a sharp impurity concentration peak. Such a structure forms a steep potential slope that allows holes generated in the vicinity of the interface on the back side to be efficiently collected in an accumulation region, thereby improving the sensitivity of the device and reducing color mixing in adjacent pixels.

If the n-type semiconductor region 119 is disposed in contact with the interface of the insulating film on the back side, the addition of arsenic to the silicon substrate can reduce crystal lattice strain. Since the n-type semiconductor region 119 mainly contains arsenic, the n-type semiconductor region 119 can have high impurity concentration only in the vicinity of the interface. Such a structure can lower the number of interface states and reduce generation of the dark current caused by the lattice deficiency at the interface.

### Second Embodiment

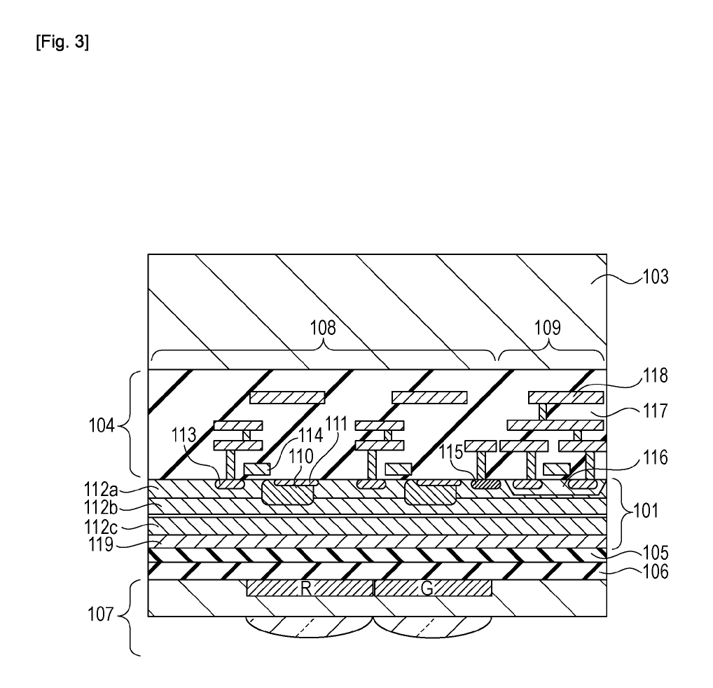

FIG. 3 is a schematic cross-sectional view of a solid-state image pickup device according to a second embodiment of the present invention. Components having the same function as in the first embodiment are denoted by the same reference numerals and will not be further described.

The present embodiment is different from the first embodiment in that the n-type semiconductor region 119 and the pixel well 112 extend to the peripheral circuit region 109. The n-type semiconductor region 119 and the pixel well 112 may entirely or partly cover the peripheral circuit region 109. It is desirable that the n-type semiconductor region 119 and the pixel well 112 be disposed all along the entire surface of the chip. In other words, as illustrated in FIG. 3, it is desirable that the n-type semiconductor region 119 and the pixel well 112 extend to the ends of the chip along the surface of the PD substrate 101.

In the present embodiment, the peripheral circuit well 116 has a higher impurity concentration than the pixel well 112. The impurity concentration of the peripheral circuit well 116 may be three times larger than that of the pixel well 112.

A process for manufacturing a solid-state image pickup device according to the present embodiment will be described below. The manufacturing process according to the present embodiment is different from the manufacturing process according to the first embodiment in the ion implantation step of forming the n-type semiconductor region 119 and the pixel well 112. In the manufacturing process according to the first embodiment, as illustrated in FIG. 2A, ion implantation using a resist mask is performed such that only the pixel region 108 is doped with an impurity. In the present embodiment, a resist mask having an opening extending to the peripheral circuit region 109 is used in ion implantation. The resist mask may have an opening corresponding to the entire peripheral circuit region 109 or part of the peripheral circuit region 109.

When the n-type semiconductor region 119 and the pixel well 112 are formed over the entire surface of the PD substrate 101, ion implantation is performed over the entire surface of the PD substrate 101 without using a resist mask.

In the present embodiment, in a step of forming peripheral circuitry, the peripheral circuit well 116 has a higher impurity concentration than the pixel well 112.

Except for those described above, the solid-state image pickup device according to the present embodiment can be manufactured by the same process as the manufacturing process according to the first embodiment.

The solid-state image pickup device according to the present embodiment has the following advantages in addition to the advantages of the first embodiment.

The manufacture of a backside-illuminated solid-state image pickup element requires precise alignment between the structure on the front side and the structure on the back side. As in the manufacturing process according to the first embodiment, processing both sides of the substrate makes the alignment difficult. In the present embodiment, the pixel well 112 and the n-type semiconductor region 119 extend to the peripheral circuit region 109. Such a structure makes the alignment easier and consequently simplifies the manufacturing process.

A structure in which the pixel well 112 and the n-type semiconductor region 119 are disposed all along the entire surface of the chip can further facilitate the alignment. In addition, use of no resist mask can reduce the number of steps and manufacturing costs.

### Third Embodiment

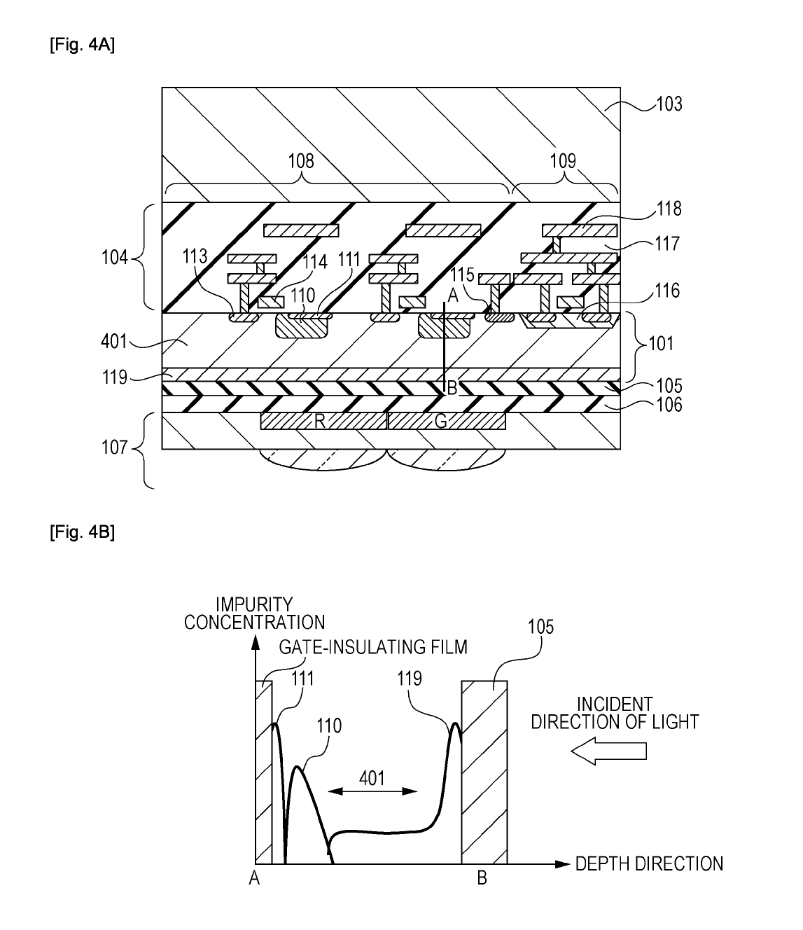

FIG. 4A is a schematic cross-sectional view of a solid-state image pickup device according to a third embodiment of the present invention. Components having the same function as in the first and second embodiments are denoted by the same reference numerals and will not be further described.

The present embodiment is different from the first and second embodiments in that the region between the n-type semiconductor region 119 and the p-type semiconductor region 110 is an n-type semiconductor region 401 having a substantially uniform impurity distribution. The n-type semiconductor region 401 may be the PD substrate 101. This is because the semiconductor substrate is considered to have a substantially uniform impurity distribution. A semiconductor layer having a substantially uniform impurity distribution may be formed by epitaxial growth. In the present embodiment, the n-type semiconductor region 401 corresponds to the second n-type semiconductor region in the Claims.

FIG. 4B is an impurity concentration profile along the line AB in FIG. 4A. The vertical axis represents the impurity concentration, and the horizontal axis represents the depth from the surface.

As illustrated in FIG. 4B, since the n-type semiconductor region 119 has a sharp impurity concentration peak, holes generated by photoelectric conversion in the vicinity of the back side move fast toward the n-type semiconductor region 401. Since the n-type semiconductor region 401 has a substantially uniform impurity distribution and a low impurity concentration, holes do not significantly diffuse in the n-type semiconductor region 401 and move efficiently toward the p-type semiconductor region 110.

Furthermore, since the n-type semiconductor region 401 has a relatively low impurity concentration, holes have high mobility. A structure in which holes are transferred to the p-type semiconductor region 110 by depleting the n-type semiconductor region 401 allows more efficient transfer of holes.

A process for manufacturing a solid-state image pickup device according to the present embodiment will be described below. This process is different from the manufacturing process according to the first embodiment in the PD substrate 101 initially used. In the present embodiment, an n-type semiconductor substrate or a semiconductor substrate on which an n-type epitaxial layer is formed can be used as the PD substrate 101.

As illustrated in FIG. 2A, the manufacturing process according to the first embodiment includes an ion implantation step of forming the n-type semiconductor region 119 and an ion implantation step of forming the pixel well 112. On the other hand, the ion implantation step of forming the pixel well 112 is not performed in the present embodiment.

Except for those described above, the solid-state image pickup device according to the present embodiment can be manufactured by the same process as the manu-facturing process according to the first embodiment.

The solid-state image pickup device according to the present embodiment has the following advantages in addition to the advantages of the first embodiment.

The solid-state image pickup device according to the present embodiment has the n-type semiconductor region 401 having a substantially uniform impurity distribution between the n-type semiconductor region 119 and the p-type semiconductor region 110. Such a structure can reduce the diffusion of holes and allows holes to be efficiently collected in the p-type semiconductor region 110, thus further improving the sensitivity of the device.

In the manufacturing process according to the present embodiment, the PD substrate 101 can be used as the n-type semiconductor region 401. This obviates the necessity of ion implantation for forming the n-type semiconductor region 401. This increases the number of the feasible designs of the photoelectric conversion portion in the depth direction.

### Fourth Embodiment

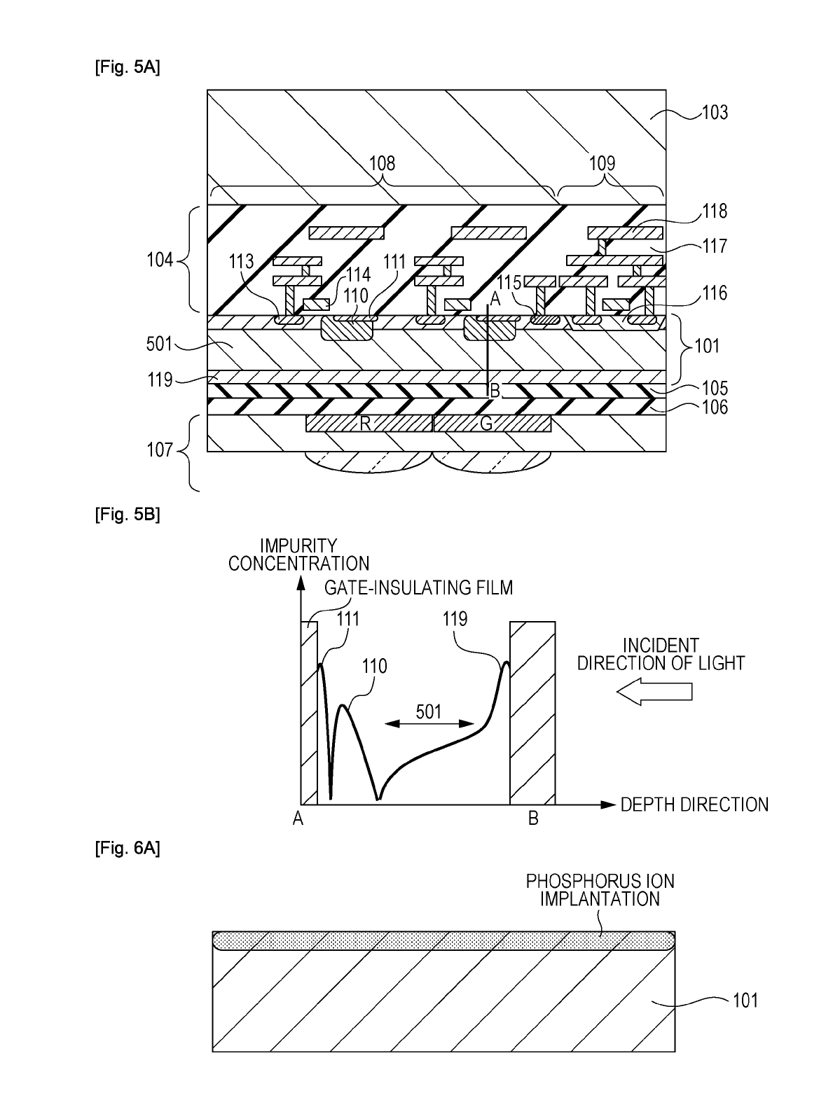

FIG. 5A is a schematic cross-sectional view of a solid-state image pickup device according to a fourth embodiment of the present invention. Components having the same function as in the first to third embodiments are denoted by the same reference numerals and will not be further described.

The present embodiment is different from the first to third embodiments in that a pixel well 501 having an impurity concentration decreasing toward the p-type semiconductor region 110 is disposed between the n-type semiconductor region 119 and the p-type semiconductor region 110.

The pixel well 501 is an n-type semiconductor region that contains phosphorus or arsenic as a principal impurity. The pixel well 501 has a smooth concentration gradient from the n-type semiconductor region 119 to the p-type semiconductor region 110. One region of the pixel well 501 closer to the front side has a lower impurity concentration than the other region of the pixel well 501 away from the front side.

Alternatively, the pixel well 501 may be composed of a plurality of semiconductor regions at different depths as in the pixel well 112 in the first embodiment, but unlike the first embodiment, the impurity concentration peaks of the semiconductor regions decrease toward the p-type semiconductor region 110. In the present embodiment, the pixel well 501 corresponds to the second n-type semiconductor region in the Claims.

FIG. 5B is an impurity concentration profile along the line AB in FIG. 5A. The vertical axis represents the impurity concentration, and the horizontal axis represents the depth from the surface.

As illustrated in FIG. 5B, since the n-type semiconductor region 119 has a sharp impurity concentration peak, holes generated by photoelectric conversion in the vicinity of the back side move fast to the pixel well 501.

The pixel well 501 has an impurity concentration decreasing from the n-type semiconductor region 119 to the p-type semiconductor region 110. Such an impurity distribution generates an electric field from the back side to the front side in the depth direction, promoting the movement of holes toward the p-type semiconductor region 110.

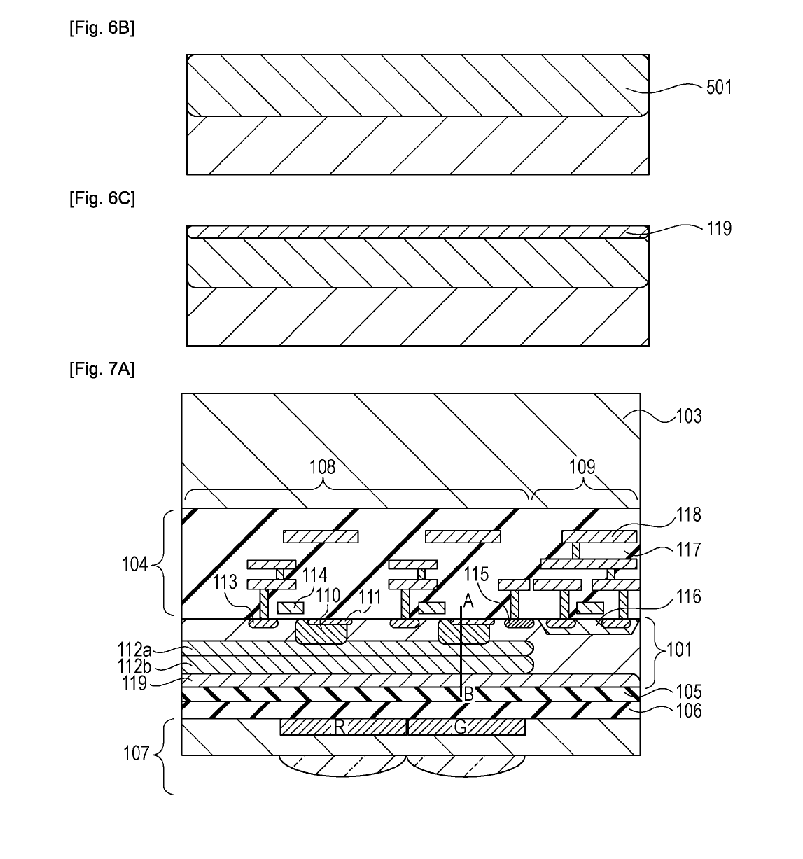

A manufacturing process according to the present embodiment will be described below with reference to the drawings. As illustrated in FIG. 6A, a p-type silicon substrate is used as the PD substrate 101, and phosphorus ions are implanted in a region as shallow as possible on the back side of the PD substrate 101 (the upper side in the drawing).

As illustrated in FIG. 6B, phosphorus is then diffused by thermal diffusion to form the pixel well 501.

As illustrated in FIG. 6C, arsenic ion implantation is then performed to form the n-type semiconductor region 119. Subsequently, the steps illustrated in FIGS. 2B to 2E in the first embodiment are performed.

Ion implantation of the pixel well 112 in the manufacturing method according to the first embodiment may be performed more than once at different implantation energies. In this case, the structure according to the present embodiment can be constructed by ion implantation under such conditions that the dose decreases with increasing implantation energy.

The solid-state image pickup device according to the present embodiment has the following advantages in addition to the advantages of the first embodiment.

The solid-state image pickup device according to the present embodiment includes the pixel well 501 having an impurity concentration decreasing toward the p-type semiconductor region 110. Such a structure allows holes to be efficiently collected in the p-type semiconductor region 110, thereby improving the sensitivity of the device and reducing color mixing.

In the manufacturing process according to the present embodiment, the pixel well 501 is formed by thermal diffusion. This can reduce manufacturing costs. Thus, the sensitivity of the device can be improved at low cost.

### Fifth Embodiment

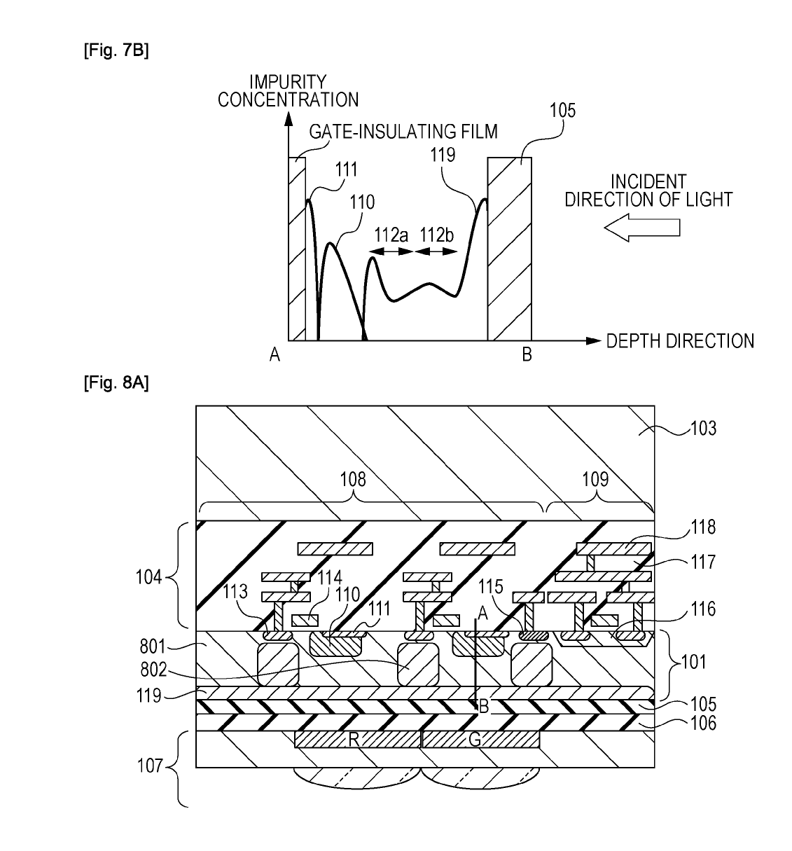

A solid-state image pickup device according to a fifth embodiment of the present invention will be described below. As illustrated in FIG. 7A, in the solid-state image pickup device according to the present embodiment, the pixel well 112 includes n-type semiconductor regions 112a and 112b at different depths from the back side.

FIG. 7B shows an impurity distribution of a pixel portion in the depth direction. Among the n-type semiconductor regions in the pixel well 112, the n-type semiconductor region 112a disposed closer to the front side (a side on which a wiring portion is disposed) has a higher impurity concentration. The n-type semiconductor region 119 has a higher impurity concentration than the n-type semiconductor region 112a.

The n-type semiconductor region 112a of the plurality of n-type semiconductor regions of the pixel well 112 closer to the front side (a side on which a wiring portion is disposed) is disposed below the p-type semiconductor region 110 so as to be in contact with the p-type semiconductor region 110. Thus, the p-type semiconductor region 110 and the pixel well 112 constitute a p-n junction.

In the solid-state image pickup device according to the present embodiment, the n-type semiconductor region 119 contains arsenic as the dominant impurity. This improves the sensitivity of the device and reduces color mixing. This can also reduce dark current and provide low-noise images.

In the solid-state image pickup device according to the present embodiment, the p-type semiconductor region 110 and the n-type semiconductor region 112a constitute a p-n junction, both of which have a relatively high impurity concentration. Such a structure can reduce the expansion of a depletion layer in the p-type semiconductor region 110. In particular, even when the impurity concentration of the p-type semiconductor region 110 is increased to improve the saturation charge amount, the impurity concentration of the n-type semiconductor region 112a directly below the p-type semiconductor region 110 can be increased to reduce the expansion of the depletion layer. This can reduce the driving voltage in signal readout and consequently reduce the power consumption of the device.

### Sixth Embodiment

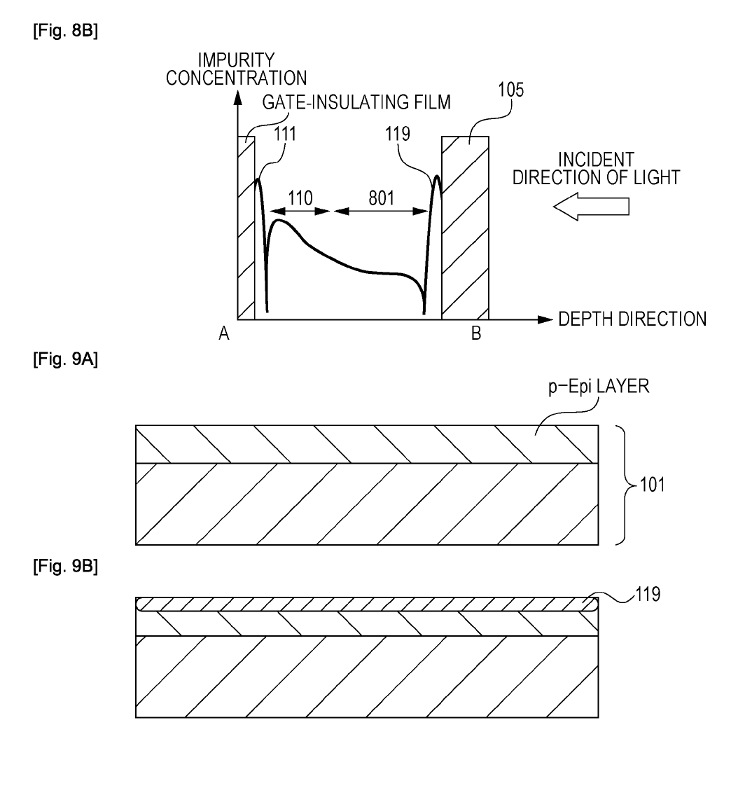

FIG. 8A is a schematic cross-sectional view of a solid-state image pickup device according to a sixth embodiment of the present invention. Components having the same function as in the first to fifth embodiments are denoted by the same reference numerals and will not be further described.

In the present embodiment, a p-type semiconductor region 801 having a lower impurity concentration than the p-type semiconductor region 110 is disposed in a region between the n-type semiconductor region 119 and the p-type semiconductor region 110. The p-type semiconductor region 801 may be a substantially intrinsic semiconductor region. The p-type semiconductor region 801 may be the p-type PD substrate 101. In the present embodiment, the p-type semiconductor region 801 corresponds to the second p-type semiconductor region in the Claims.

An n-type semiconductor region 802 is disposed between the pixels in the PD substrate 101. It is desirable that the end portion of the n-type semiconductor region 802 on the back side be in contact with the n-type semiconductor region 119.

The n-type semiconductor region 802 provides a potential barrier to holes. The n-type semiconductor region 802 between photoelectric conversion portions of adjacent two pixels therefore functions as a pixel isolation portion. The n-type semiconductor region 802 prevents holes in the p-type semiconductor region 801 from entering the adjacent pixels.

Part of the n-type semiconductor region may be connected to a well contact region 115. In this case, the electric potential of the n-type semiconductor region 119 can be controlled through the n-type semiconductor region 802.

In the operation of the solid-state image pickup device, before hole accumulation is initiated, a bias is applied to the p-type semiconductor region 110 to reset the semiconductor region 110. In the present embodiment, the p-type semiconductor region 801 may be substantially or completely depleted at the same time.

If the n-type semiconductor region 119 and the n-type semiconductor region 802 have a sufficiently higher impurity concentration than the p-type semiconductor region 801, the width W of a depletion layer in the p-type semiconductor region is expressed by the following equation:

$$W = \sqrt{\frac{2 {E}_{Si} ( P - V )}{{qN}_{A}}} \qquad [ Math . 1 ]$$

wherein E_{Si} (epsilon) denotes the dielectric constant of silicon, q denotes the elementary charge, N_{A} denotes the impurity concentration of the p-type semiconductor region 801, P (phi) denotes the built-in potential between the p-type semiconductor region 801 and the surrounding n-type semiconductor regions, and V denotes the reset voltage.

If the width W of the depletion layer satisfies the following condition for the smaller one d of the depth d1 and the width d2 of the p-type semiconductor region 801, the p-type semiconductor region 801 is completely depleted.

$$W \leq \frac{d}{2} \qquad [ Math . 2 ]$$

More specifically, when the p-type semiconductor region 801 has a depth of two micrometers, a width of two micrometers, a reset voltage V of −5 V, and an impurity concentration N_{A} of 6.5E15 cm⁻³ or less, the p-type semiconductor region 801 satisfies the complete depletion condition.

In brief, if the smaller one of the depth and the width of the p-type semiconductor region 801 is n micrometers, the impurity concentration N_{A} satisfying the following condition results in complete depletion.

$${N}_{A} \leq {( \frac{n}{2} )}^{2} \times 6.5 E 15 \qquad [ Math . 3 ]$$

FIG. 8B is an impurity concentration profile along the line AB in FIG. 8A. The vertical axis represents the impurity concentration, and the horizontal axis represents the depth from the surface.

In the present embodiment, the p-type semiconductor region 801 is disposed between the n-type semiconductor region 119 and the p-type semiconductor region 110. The impurity concentration of the p-type semiconductor region 801 is lower than the impurity concentrations of the other semiconductor regions and is substantially the same as the impurity concentration of the substrate. This results in depletion in the p-type semiconductor region 801. The electric field in the depletion layer accelerates the movement of holes to the p-type semiconductor region 110.

The n-type semiconductor region 119 contains arsenic as a principal impurity and can therefore have a sharp impurity concentration peak in the vicinity of the back side. In other words, a semiconductor region having a high impurity concentration is disposed in a shallow region on the back side. The depletion layer in the p-type semiconductor region 801 therefore extends close to the back side, allowing a large number of electric charges to be collected in the p-type semiconductor region 110. However, since the depletion layer does not come into contact with the interface on the back side, the dark current can be reduced.

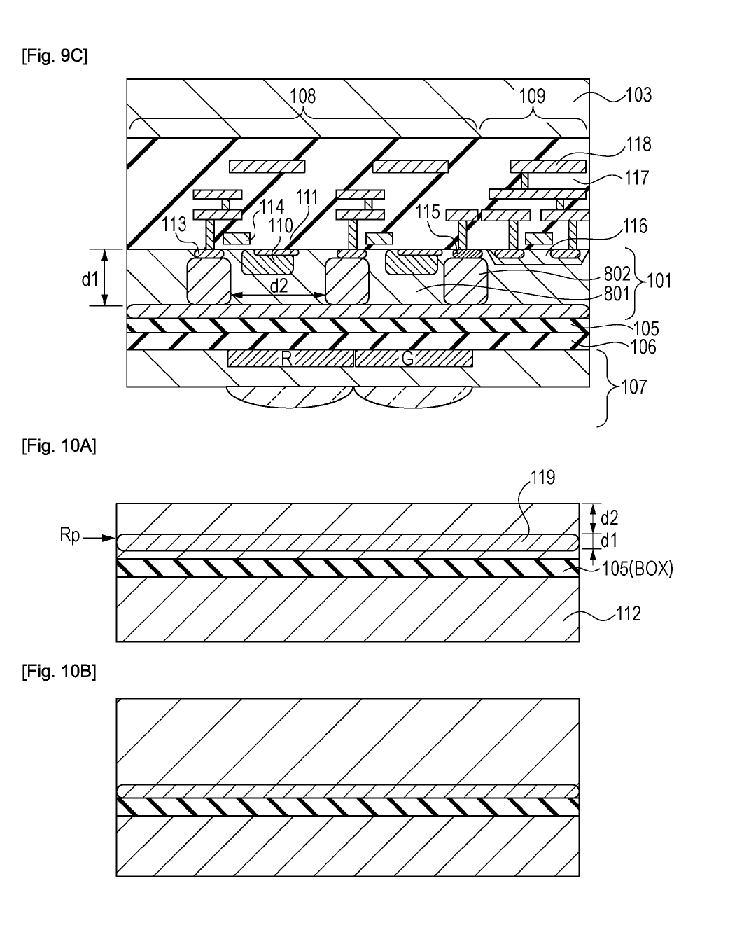

A manufacturing process according to the present embodiment will be described below with reference to the drawings. As illustrated in FIG. 9A, a substrate in which a p-type semiconductor region is epitaxially grown on a silicon substrate is used as the PD substrate 101. A p-type silicon substrate may also be used as the PD substrate 101.

As illustrated in FIG. 9B, ion implantation is performed in a shallow region on the back side to form the n-type semiconductor region 119. Subsequently, the steps illustrated in FIGS. 2B and 2C in the first embodiment are performed.

Subsequently, the step illustrated in FIG. 2D in the first embodiment is performed. During this step, the n-type semiconductor regions 802 are formed, as illustrated in FIG. 9C. The same step as in the first embodiment is subsequently performed.

The solid-state image pickup device according to the present embodiment has the following advantages in addition to the advantages of the first embodiment.

The depletion layer in the p-type semiconductor region 801 extends to the vicinity of the interface on the back side. The electric field in the depletion layer allows holes generated in the vicinity of the interface on the back side to be efficiently collected in the p-type semiconductor region 110. Such a structure can further improve the sensitivity of the device.

The solid-state image pickup device according to the present embodiment includes the n-type semiconductor region 802. The n-type semiconductor region 802 can prevent holes in the p-type semiconductor region 801 from entering adjacent pixels. This can further reduce color mixing.

Such a structure that includes a pixel isolation portion can also be applied to the solid-state image pickup devices according to the first to fifth embodiments.

### Seventh Embodiment

A process for manufacturing a solid-state image pickup device according to a seventh embodiment of the present invention will be described below with reference to the drawings. In this manufacturing process, element structures are formed on a silicon-on-insulator (SOI) substrate. The SOI layer functions as the PD substrate 101. And a bulk substrate functions as the processing substrate 102. An interface between the SOI layer and a buried oxide (BOX) layer is the back side and a light incident surface.

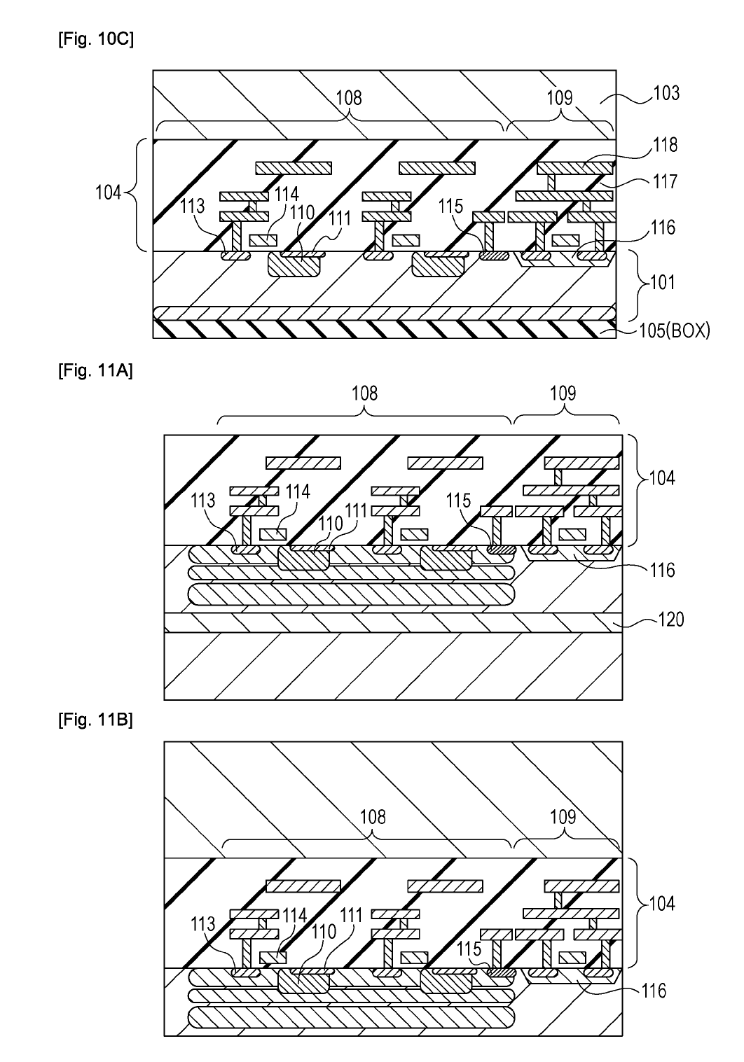

First, as illustrated in FIG. 10A, arsenic ion implantation is performed in the vicinity of the interface between the SOI layer and the BOX layer to form the n-type semiconductor region 119. The implantation energy conditions are desirably such that the depth Rp of an impurity concentration peak is at least 3DRp away from the front side of the SOI layer and at least 3DRp away from the interface between the SOI layer and the BOX layer. DRp denotes the standard deviation of impurity concentration in the depth direction and indicates the variance from the depth Rp of an impurity concentration peak. For example, when the impurity concentration peak is within 3DRp from the interface between the SOI layer and the BOX layer, a large amount of impurity is captured into the BOX layer, thus causing fluctuation in impurity concentration. The above-mentioned conditions can reduce the fluctuation attributed to processes and stabilize the impurity concentration.

As illustrated in FIG. 10B, a silicon film is formed on the SOI layer by epitaxial growth to increase the thickness of the SOI layer. This allows the n-type semiconductor region 119 to be formed deep in the surface even by low-energy ion implantation. A lower ion implantation energy generally results in a smaller DRp and consequently tends to result in an impurity distribution having a steep concentration gradient. A deeper pixel structure can improve the sensitivity particularly of long-wavelength light.

In the drawing, although arsenic ion implantation is performed over the entire surface, ion implantation may be performed only in the pixel region 108 using a mask, as illustrated in FIG. 2A in the first embodiment.

In the present manufacturing process, the SOI layer is an n-type semiconductor region. As in the embodiments described above, phosphorus ion implantation may be performed to form the pixel well 112. Instead, the SOI layer may be a p-type semiconductor region.

Subsequently, as illustrated in FIG. 10C, semiconductor regions in the pixel region 108 and the peripheral circuit region 109 and the wiring portion 104 can be formed in the SOI layer by a known method. The supporting substrate 103 is then attached to a side of the wiring portion 104 opposite to the PD substrate 101.

Finally, the bulk substrate functioning as the processing substrate 102 is removed from the BOX layer. If necessary, the protective film 106 and the optical function portion 107 are formed on the back side.

### Eighth Embodiment

A process for manufacturing a solid-state image pickup device according to an eighth embodiment of the present invention will be described below with reference to the drawings.

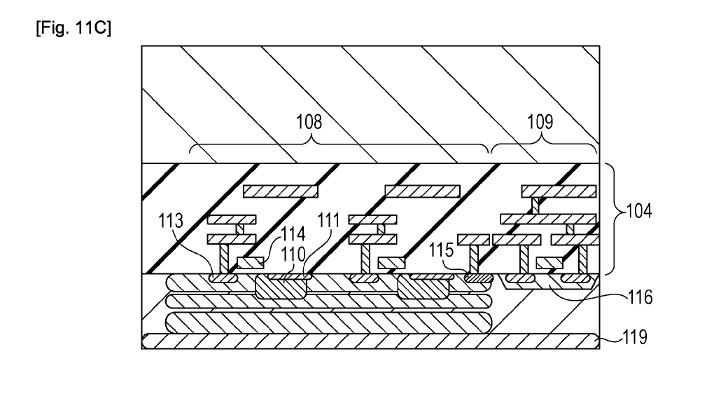

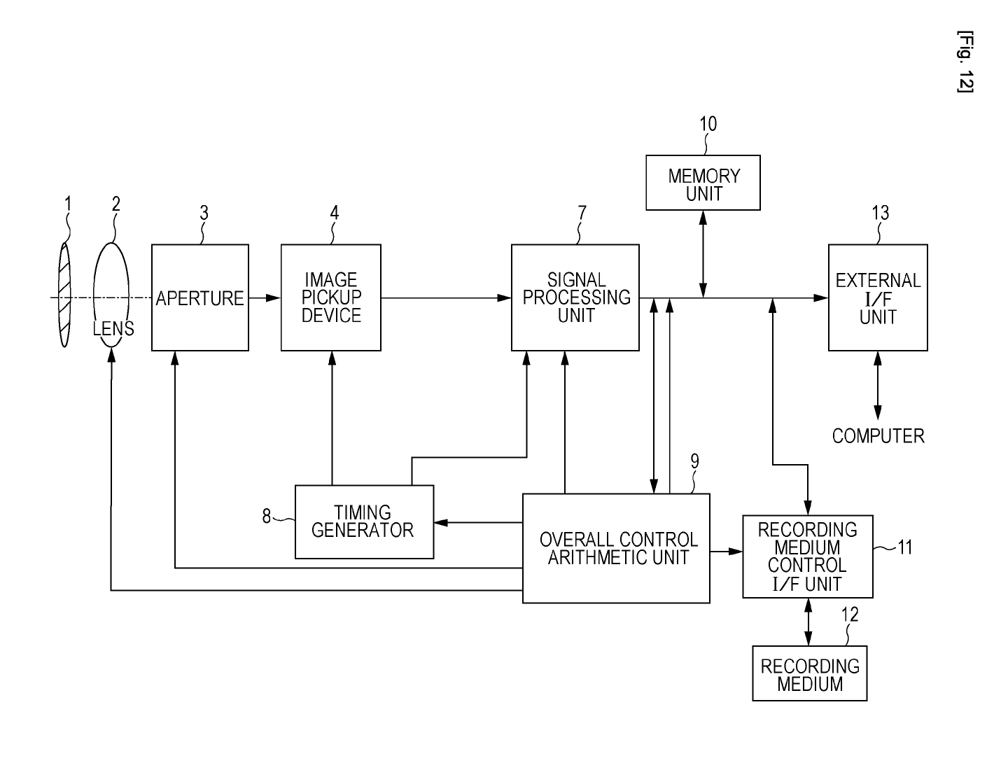

In the present manufacturing process, the PD substrate 101 is a p-type silicon substrate. As illustrated in FIG. 11A, the separation layer 120, semiconductor regions in the pixel region 108 and the peripheral circuit region 109, and the wiring portion 104 can be formed by a known method. The present manufacturing process is different from the manufacturing process illustrated in FIG. 2 in that the formation of the n-type semiconductor region 119 by arsenic ion implantation is not performed in this step.

Subsequently, as illustrated in FIG. 11B, the supporting substrate 103 is attached to the wiring portion 104, and the back side of the PD substrate 101 is removed with the separation layer 120 as a boundary.

Subsequently, as illustrated in FIG. 11C, the n-type semiconductor region 119 is formed in the vicinity of the back side of the PD substrate 101. For example, the n-type semiconductor region 119 can be formed by arsenic ion implantation on the back side and activation by laser spike annealing. A wiring portion or an adhesive sometimes makes ion implantation difficult. In that case, an impurity may be doped, for example, by plasma doping.

Finally, the protective film 106 and the optical function portion 107 are formed on the back side, if necessary.

### Ninth Embodiment

The present embodiment describes a camera system that includes a solid-state image pickup device according to an embodiment of the present invention. Examples of image pickup systems include, but are not limited to, digital still cameras and digital camcorders. FIG. 12 is a block diagram of a digital still camera that includes a photoelectric conversion device.

The digital still camera includes a lens protection barrier 1, a lens 2 for forming an optical image of an object on a solid-state image pickup device 4, and an aperture 3 for altering the amount of light passing through the lens 2. The solid-state image pickup device 4 is one of the solid-state image pickup devices described in the previous embodiments and converts optical images formed by the lens 2 into image data. The solid-state image pickup device 4 includes an analog-to-digital (AD) converter on a substrate. A signal processing unit 7 performs various corrections and compression of image data output from the solid-state image pickup device 4. A timing generator 8 outputs various timing signals to the solid-state image pickup device 4 and the signal processing unit 7. An overall control arithmetic unit 9 controls various operations and the entire digital still camera. A memory unit 10 temporarily stores image data. An interface unit 11 performs recording on or readout from a recording medium. A recording medium 12 is a removable recording medium, such as a semiconductor memory, for recording or readout of image data. An interface unit 13 mediates communication with an external computer. Timing signals may be input from the outside of the image pickup system. Thus, at a minimum, the image pickup system includes the solid-state image pickup device 4 and the signal processing unit 7 for processing imaging signals output from the solid-state image pickup device.

Although the solid-state image pickup device 4 and the AD converter are disposed on the same substrate in the present embodiment, the solid-state image pickup device 4 and the AD converter may be disposed on different substrates. The solid-state image pickup device 4 and the signal processing unit 7 may be disposed on the same substrate.

As described above, a solid-state image pickup device according to an embodiment of the present invention can be applied to a camera system. A camera system that includes a solid-state image pickup device according to an embodiment of the present invention can capture images with high sensitivity.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-276834, filed Dec. 4, 2009, which is hereby incorporated by reference herein in its entirety.

### REFERENCE SIGNS LIST

101 PD substrate
102 Processing substrate
103 Supporting substrate
104 Wiring portion
105 Insulating film
106 Protective film
107 Optical function portion
108 Pixel region
109 Peripheral circuit region
110 Accumulation region
111 High-concentration n-type semiconductor region
112 Pixel well
113 Floating diffusion
114 Transfer gate electrode
115 Well contact region
116 Peripheral circuit well
117 Interlayer insulating film
118 Wiring
119 N-type semiconductor region
120 Separation layer

1. A backside-illuminated solid-state image pickup device comprising:
a semiconductor substrate in which a plurality of pixels each having a photoelectric conversion portion are disposed;
a plurality of wiring layers disposed on a first main surface side of the semiconductor substrate; and
an interlayer insulating film disposed between the plurality of wiring layers,
wherein light enters the photoelectric conversion portion from a second main surface opposite to the first main surface of the semiconductor substrate,
the photoelectric conversion portion includes a first n-type semiconductor region and a first p-type semiconductor region,
the first n-type semiconductor region contains arsenic as a principal impurity,
the first n-type semiconductor region is disposed closer to the second main surface of the semiconductor substrate than the first p-type semiconductor region is, and
a hole generated by photoelectric conversion is collected in the first p-type semiconductor region as a signal carrier.

2. The solid-state image pickup device according to claim 1, wherein an insulating film is disposed on the second main surface of the semiconductor substrate, and
the first n-type semiconductor region is disposed in contact with the insulating film.

3. The solid-state image pickup device according to claim 1, wherein an n-type semiconductor region is disposed between the first p-type semiconductor region and the first main surface.

4. The solid-state image pickup device according to claim 1, wherein the semiconductor substrate includes a pixel region in which the plurality of pixels are disposed and a peripheral circuit region in which a signal-processing circuit configured to process signals from the pixels is disposed, and
the first n-type semiconductor region extends to the peripheral circuit region along the first main surface of the semiconductor substrate.

5. The solid-state image pickup device according to claim 4, wherein the first n-type semiconductor region extends to an end of the semiconductor substrate along the first main surface of the semiconductor substrate.

6. The solid-state image pickup device according to claim 1, wherein a second p-type semiconductor region is disposed between the first p-type semiconductor region and the first n-type semiconductor region, and
the second p-type semiconductor region is completely depleted.

7. The solid-state image pickup device according to claim 6, wherein the semiconductor substrate includes a pixel region in which the plurality of pixels are disposed and a peripheral circuit region in which a signal-processing circuit configured to process signals from the pixels is disposed, and
the second p-type semiconductor region extends to the peripheral circuit region along the first main surface of the semiconductor substrate.

8. The solid-state image pickup device according to claim 7, wherein the second p-type semiconductor region extends to an end of the semiconductor substrate along the first main surface of the semiconductor substrate.

9. The solid-state image pickup device according to claim 1, wherein a second n-type semiconductor region is disposed between the first p-type semiconductor region and the first n-type semiconductor region.

10. The solid-state image pickup device according to claim 9, wherein the second n-type semiconductor region includes two n-type semiconductor subregions at different depths from the first main surface of the semiconductor substrate, and
one of the two n-type semiconductor subregions closer to the first main surface than the other has a lower impurity concentration than the other subregion.

11. The solid-state image pickup device according to claim 9, wherein the second n-type semiconductor region includes a plurality of n-type semiconductor subregions at different depths from the first main surface of the semiconductor substrate,
one of the plurality of n-type semiconductor subregions which is closest to the first main surface has the highest impurity concentration among the plurality of the n-type semiconductor subregions, and the first n-type semiconductor region has a higher impurity concentration than the n-type semiconductor subregion closest to the first main surface.

12. The solid-state image pickup device according to claim 9, wherein the second n-type semiconductor region has a substantially uniform impurity distribution.

13. The solid-state image pickup device according to claim 9, wherein the semiconductor substrate includes a pixel region in which the plurality of pixels are disposed and a peripheral circuit region in which a signal-processing circuit configured to process signals from the pixels is disposed, and
the second n-type semiconductor region extends to the peripheral circuit region along the first main surface of the semiconductor substrate.

14. The solid-state image pickup device according to claim 13, wherein the second n-type semiconductor region extends to an end of the semiconductor substrate along the first main surface of the semiconductor substrate.

15. The solid-state image pickup device according to claim 1, wherein a pixel isolation portion is disposed between the first p-type semiconductor regions of adjacent pixels of the plurality of pixels.

16. The solid-state image pickup device according to claim 1, further comprising:
a floating diffusion;
a transfer portion configured to transfer a hole collected in the first p-type semiconductor region to the floating diffusion; and
a circuit configured to read signals corresponding to the number of holes transferred to the floating diffusion.

17. A method for manufacturing a backside-illuminated solid-state image pickup device, comprising:
implanting arsenic ions into a second main surface of a semiconductor substrate;
reducing the thickness of the semiconductor substrate from a first main surface side opposite to the second main surface;
attaching a processing substrate to the second main surface side of the semiconductor substrate;
forming a wiring layer on the first main surface side of the semiconductor substrate; and
removing the processing substrate.

18. A method for manufacturing a backside-illuminated solid-state image pickup device, comprising:
forming a wiring layer on a first main surface of a semiconductor substrate;
reducing the thickness of the semiconductor substrate from a second main surface side opposite to the first main surface; and
implanting arsenic ions into the second main surface of the semiconductor substrate.

19. A method for manufacturing a backside-illuminated solid-state image pickup device, comprising:
implanting arsenic ions into an SOI layer of an SOI substrate, the SOI substrate including the SOI layer, a BOX layer, and a bulk substrate;
forming a silicon film on the SOI layer by epitaxial growth;
forming a wiring layer on a side of the SOI layer opposite to the BOX layer; and
removing the bulk substrate.
